(19) United States
(12) Patent Application Publication
(10) Pub. No.: US 2025/0331252 A1
(43) Pub. Date: Oct. 23, 2025

(54) TREATING THE DIELECTRIC FILMS UNDER THE BOTTOMS OF SOURCE/DRAIN REGIONS

(71) Applicant: Taiwan Semiconductor Manufacturing Co., Ltd., Hsinchu (TW)

(72) Inventors: Ting-Hsiang Chang, New Taipei City (TW); Chung-Ting Ko, Kaohsiung City (TW); Shu Ling Liao, Taichung City (TW); Sung-En Lin, Xionglin Township (TW); Chi On Chui, Hsinchu (TW)

(21) Appl. No.: 19/258,215

(22) Filed: Jul. 2, 2025

Related U.S. Application Data
(63) Continuation of application No. 18/593,364, filed on Mar. 1, 2024.
(60) Provisional application No. 63/611,350, filed on Dec. 18, 2023.

(51) Int. Cl. H10D 62/10; H01J 37/32; H01L 21/02; H01L 21/311; H10D 30/01; H10D 30/43; H10D 30/67; H10D 64/01; H10D 84/01; H10D 84/03; H10D 84/83

(52) U.S. Cl. CPC H10D 62/121; H01L 21/02214; H01L 21/02274; H01L 21/31116; H10D 30/014; H10D 30/43; H10D 30/6735; H10D 30/6757; H10D 64/017; H10D 84/013; H10D 84/0135; H10D 84/038; H10D 84/83; H01J 37/32082; H01J 2237/3345

(57) ABSTRACT

A method includes forming a gate stack over a semiconductor region, etching the semiconductor region to form a source/drain recess aside of the gate stack, depositing a first dielectric layer, wherein a portion of the first dielectric layer is in the source/drain recess, performing a treatment process on the first dielectric layer, depositing a second dielectric layer on the first dielectric layer, and etching the second dielectric layer and the first dielectric layer. A first portion of the first dielectric layer and a second portion of the second dielectric layer remain at a bottom of the source/drain recess to form a dielectric region. A source/drain region is deposited in the source/drain recess and over the dielectric region.

### PRIORITY CLAIM AND CROSS-REFERENCE

This application is a continuation of U.S. patent application Ser. No. 18/593,364, filed on Mar. 1, 2024, which application claims the benefit of the following provisionally filed U.S. Patent application: Application No. 63/611,350, filed on Dec. 18, 2023, and entitled “METHOD FOR FABRICATING SEMICONDUCTOR DEVICE,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the cross-sectional views of intermediate stages in the formation of a Gate All-Around (GAA) transistor in accordance with some embodiments.

FIGS. 15 through 19A and 20A illustrate the cross-sectional views of intermediate stages in the formation of dielectric layers and overlying source/drain regions in accordance with some embodiments.

FIGS. 19B, 20B, 19C, and 20C illustrate the cross-sectional views of intermediate stages in the formation of dielectric regions and overlying source/drain regions in accordance with some embodiments.

FIG. 21 illustrates the deposition of a dielectric layer and the subsequent post treatment process in accordance with some embodiments.

FIG. 22 illustrates the comparison of samples that are not treated to the samples that are treated in accordance with some embodiments.

FIG. 23 illustrates a process flow for forming a GAA transistor in accordance with some embodiments.

FIG. 24 illustrates a process flow for forming dielectric regions and overlying source/drain regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate All-Around (GAA) transistor having a dielectric region including a treated dielectric layer underlying a source/drain region is provided. The methods of forming the dielectric region are provided. In accordance with some embodiments, after the deposition of a dielectric layer into source/drain recesses, a treatment process is performed to improve the quality of the dielectric layer(s). The dielectric layer is more resistant to the subsequent etching and cleaning processes. The leakage between the source/drain regions and the underlying substrate is thus reduced. The parasitic capacitance between gate electrode and source/drain regions is also reduced.

Although GAA transistors are used as an example to discuss the concept of the present disclosure, the embodiments may be applied on other types of transistors such as Fin Field-Effect Transistors (FinFETs). Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

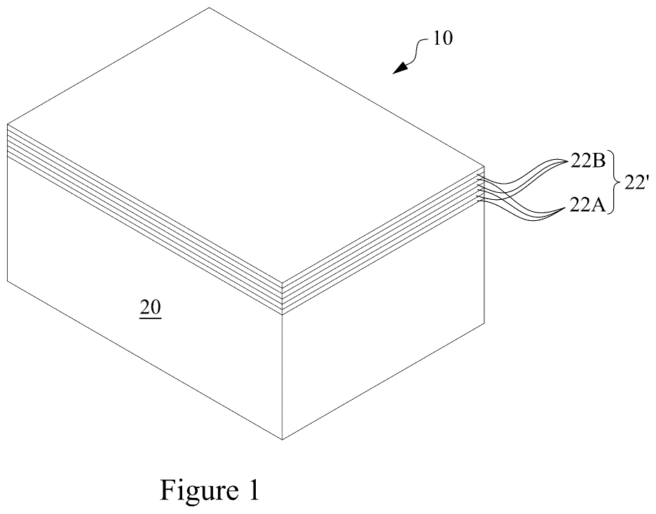

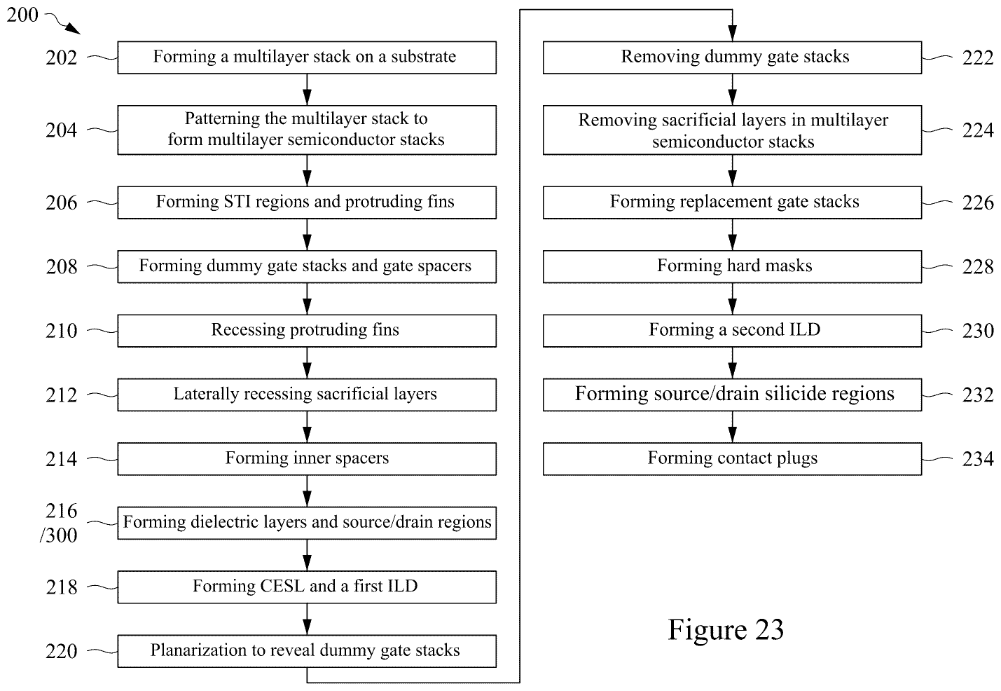

FIGS. 1-4, 5A, 5B, 6A, 6B, 7A, 7B, 8A, 8B, 9A, 9B, 10A, 10B, 11A, 11B, 12A, 12B, 13A, 13B, 14A, and 14B illustrate the cross-sectional views of intermediate stages in the formation of a GAA transistor in accordance with some embodiments of the present disclosure. The corresponding processes are also reflected schematically in the process flow shown in FIG. 23.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 23. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

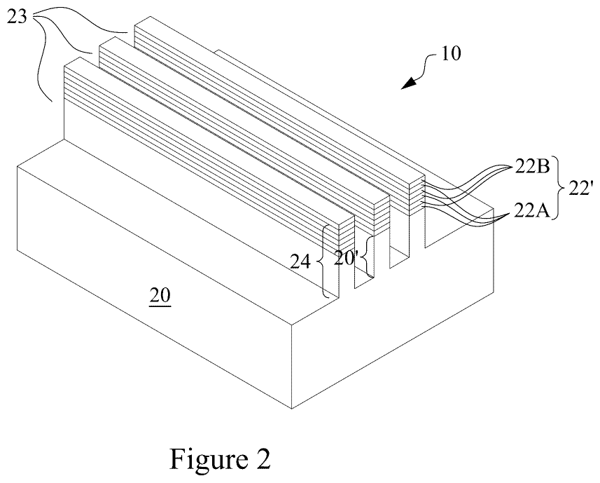

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 23. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

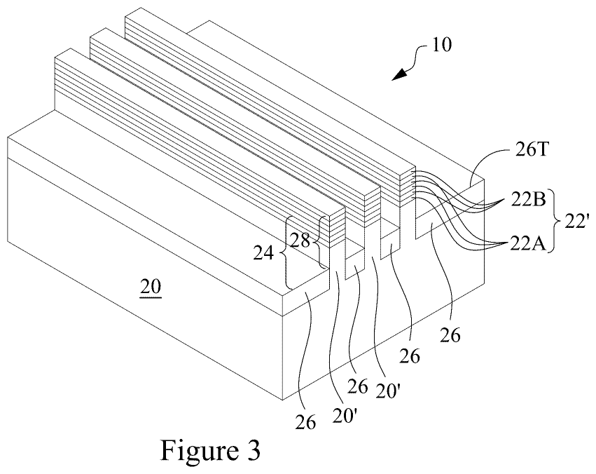

FIG. 3 illustrates the formation of isolation regions 26, which are also referred to as Shallow Trench Isolation (STI) regions throughout the description. The respective process is illustrated as process 206 in the process flow 200 shown in FIG. 23. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

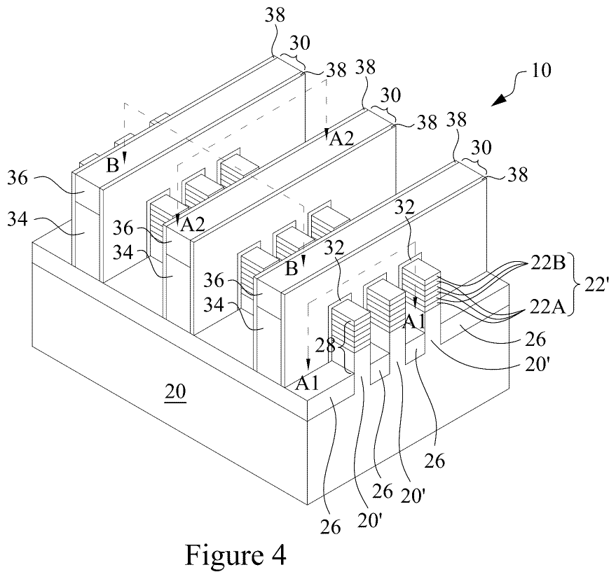

Referring to FIG. 4, dummy gate stacks 30 and gate spacers 38 are formed on the top surfaces and the sidewalls of (protruding) fins 28. The respective process is illustrated as process 208 in the process flow 200 shown in FIG. 23. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

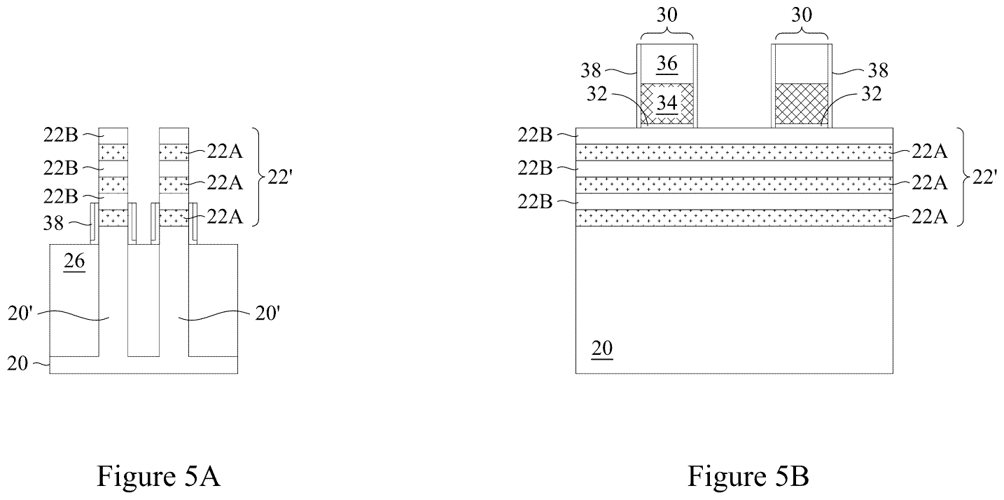

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

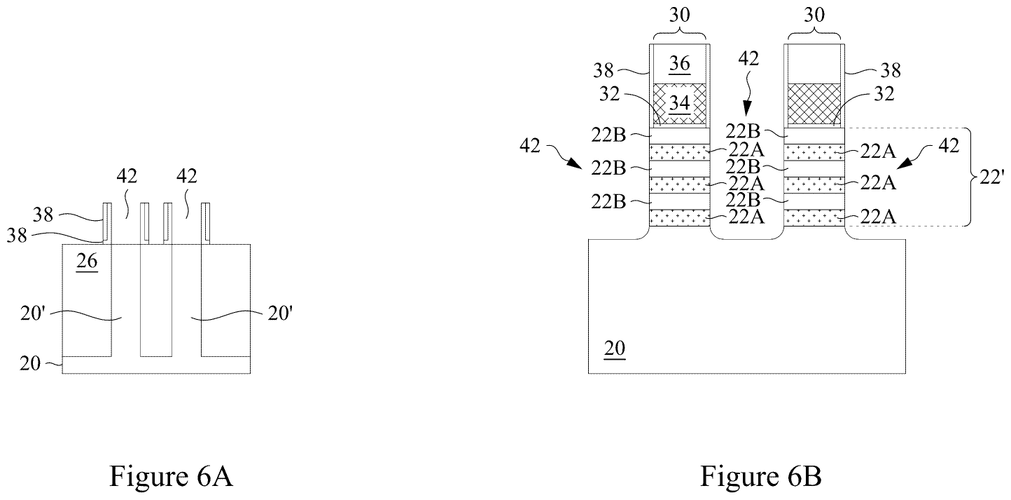

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown in FIG. 23. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

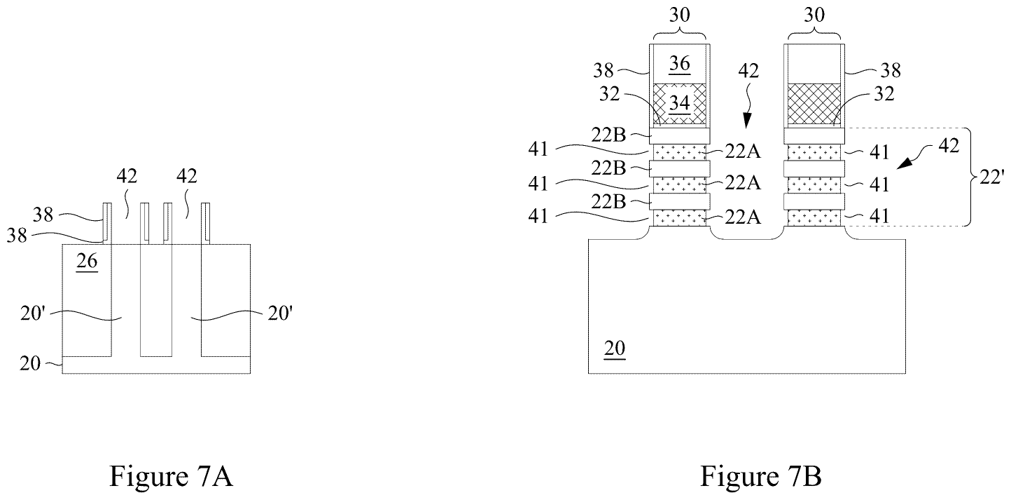

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown in FIG. 23. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

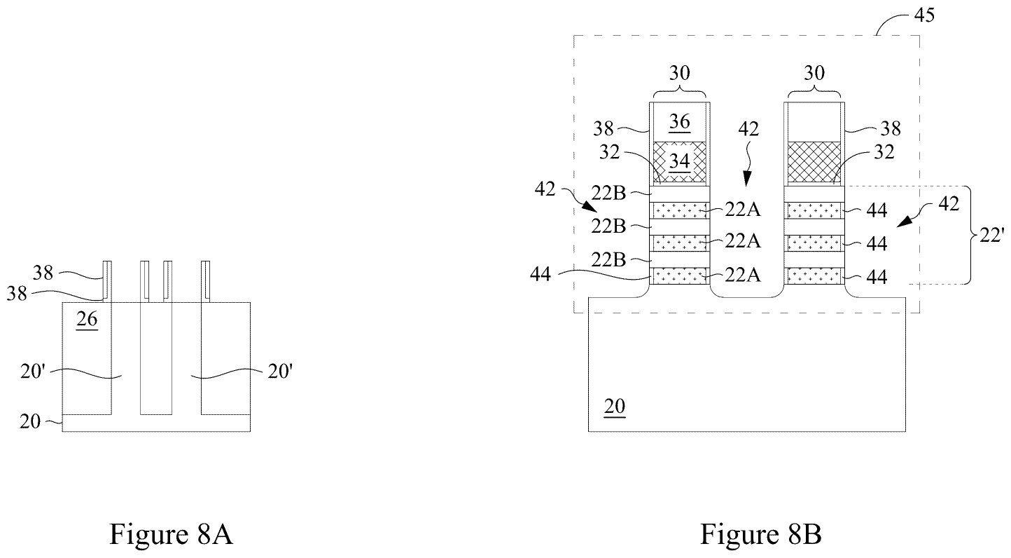

Referring to FIGS. 8A and 8B, inner spacers 44 are formed. The respective process is illustrated as process 214 in the process flow 200 shown in FIG. 23. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

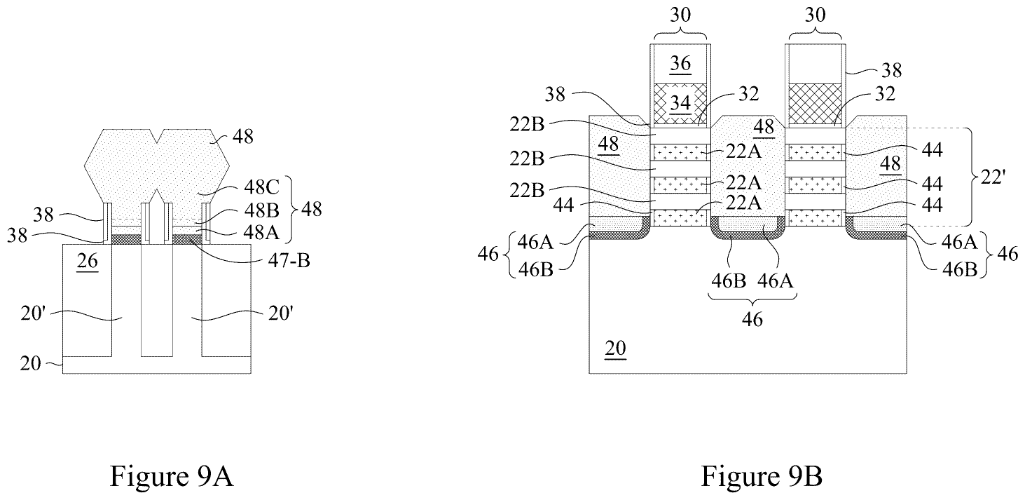

Referring to FIGS. 9A and 9B, dielectric regions 46 and epitaxial source/drain regions 48 are formed in recesses 42. The respective process is illustrated as process 216 in the process flow 200 shown in FIG. 23. In accordance with some embodiments, the source/drain regions 48 may exert stress on the nanostructures 22B, which are used as the channels of the corresponding GAA transistors, thereby improving performance. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other. Voids (air gaps) may be generated under the merged epitaxy regions 48.

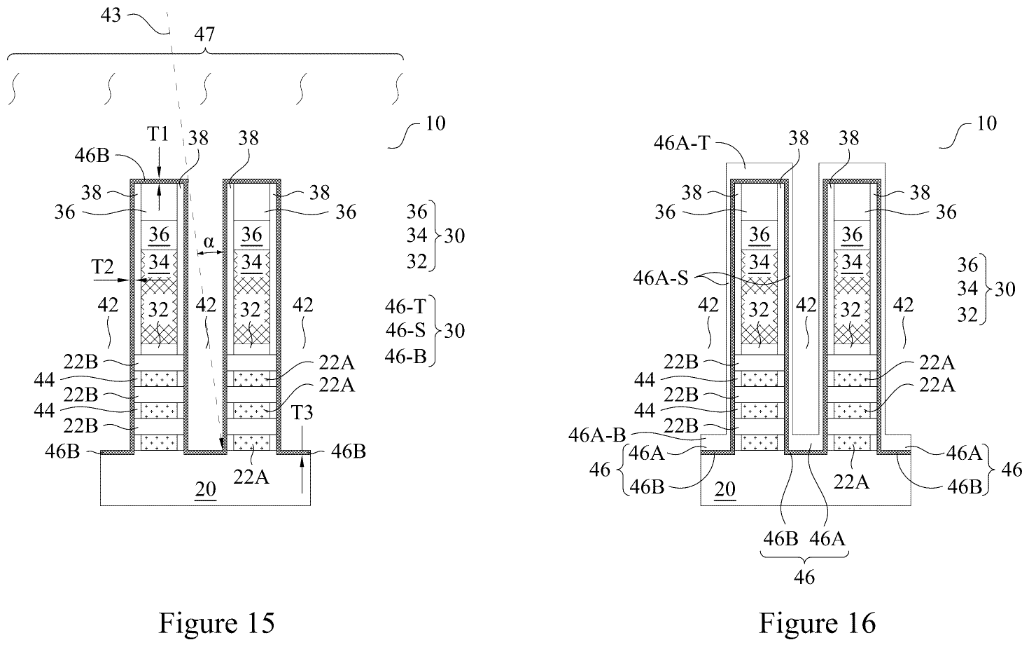

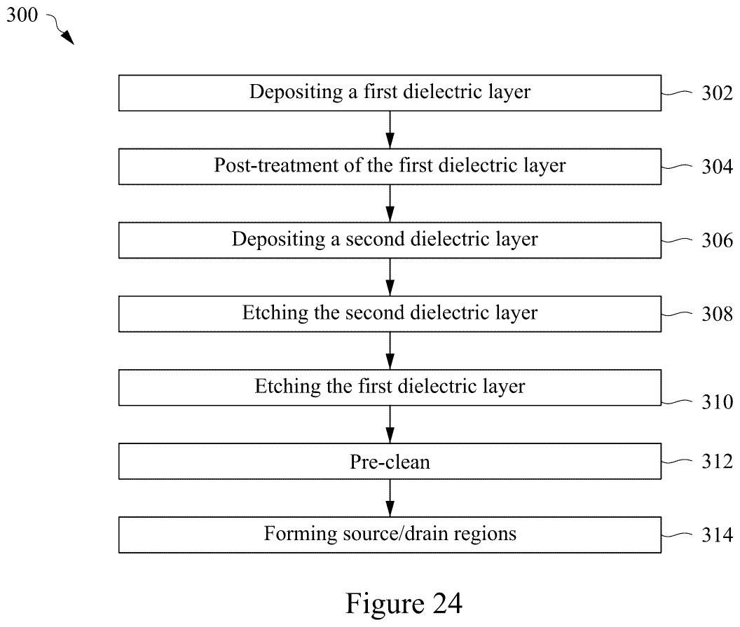

FIGS. 15-18, 19A, 19B, 19C, 20A, 20B, and 20C illustrate the details in the formation of the dielectric regions 46 and source/drain regions 48 (as shown in FIGS. 9A and 9B) in accordance with some embodiments. The processes shown in FIGS. 15-18, 19A, 19B, 19C, 20A, 20B, and 20C are also illustrated in the process flow 300 as shown in FIG. 24, wherein the process flow 300 show the details of the process 216 as shown in the process flow 200.

FIG. 15 illustrates the region 45 in FIG. 8B, in which recesses 42 and inner spacers 44 have been formed. Next, dielectric layer 46B is deposited. The respective process is illustrated as process 302 in the process flow 300 shown in FIG. 24. In accordance with some embodiments, dielectric layer 46B comprises an oxygen-comprising dielectric material such as SiON, SiO, SiOC, or the like. The corresponding precursor may include a silicon-containing precursor and an oxygen-containing precursor. The silicon-containing precursor may comprise Bis(diethylamino)silane ((BDEAS) (SiH₂[N(CH₂CH₃)₂]₂), silane, disilane, or the like, or a combination thereof. The oxygen-containing precursor may be selected from CO₂, O₂, NO₂, or the like, and combinations thereof. A carrier gas including Ar, He, or the like, or a combination thereof may be used.

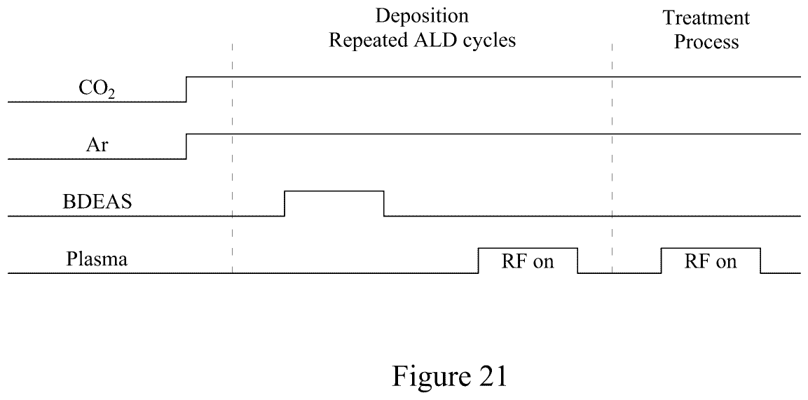

FIG. 21 illustrates an example formation process for depositing dielectric layer 46B in accordance with some embodiments. The deposition of dielectric layer 46B may be performed using Atomic Layer Deposition (ALD), Plasma Enhance ALD (PEALD), Chemical Vapor Deposition (CVD), or the like. The illustrated example process is performed using PEALD, which includes repeating a plurality of ALD cycles, while one of the ALD cycles is represented. The illustrated ALD cycle is repeated.

The example process uses BDEAS and CO₂ as the precursors, and uses Ar as the carrier gas, while other precursors and carrier gases may also be used. Plasma may be turned on at certain time to incur (and speed up) reaction and treatment. Each gas and the plasma may be represented by a line, which, when being at a higher position, represents that the gas is conducted, or the plasma is turned on, and when being at a lower position, represents that the gas is cut off, or the plasma is turned off.

In accordance with some embodiments, in an ALD cycle, CO₂ and Ar are constantly conducted. The flow rate of the oxygen-containing precursor such as CO₂ may be in the range between about 1 slm and about 10 slm. BDEAS is pulsed, and is adsorbed on wafer 10, and then is purged by the subsequently conducted Ar and CO₂. The pulsing time (feed time) may be in the range between about 0.5 seconds and about 2.5 seconds. After the purging of BDEAS, plasma is turned on by applying a Radio Frequency (RF) power to react CO₂ with the adsorbed BDEAS, hence forming SiCO in accordance with some embodiments. The ALD cycle is repeated until the thickness of dielectric layer 46B reaches a desirable value, for example, in the range between about 0.5 nm and about 2.5 nm.

In accordance with some embodiments, during the deposition of dielectric layer 46B, the wafer temperature of wafer 10 may be in the range between about 75° C. and about 390° C., or may be in the range between about 75° C. and about 100° C. The plasma may be generated using Inductively Coupled Plasmas (ICP) or Capacitively Coupled Plasma (CCP). The RF-on time (for generating plasma) may be in the range between about 0.2 seconds and about 1.2 seconds, or may be in the range between about 0.2 seconds and about 0.4 seconds. The RF power may be in the range between about 15 watts and about 600 watts.

After dielectric layer 46B is deposited, a treatment process 47 (also referred to as a post-treatment process) is performed by turning RF power and hence plasma on, as also shown in FIG. 21. The treatment process 47 is also shown in FIG. 15. The respective process is illustrated as process 304 in the process flow 300 shown in FIG. 24. The deposited dielectric layer 46B may have defects, and may have dangling bonds. In accordance with some embodiments, the treatment process 47 may attach oxygen atoms to the dangling bonds to fix the defects. The treated dielectric layer 46B thus becomes denser. For example, the density of dielectric layer 46B may be about 3 percent to about 5 percent higher than before the treatment process 47. Also, due to the elimination of the dangling bonds, the etching rate of dielectric layer 46B is reduced in subsequent etching and cleaning process. In accordance with some embodiments, the process gas used for the treatment process 47 may be selected from CO₂, O₂, NO₂, or the like, or combinations thereof. The flow rate of the process may be in the range between about 1 slm and about 10 slm.

In accordance with some embodiments, the treatment process may be performed in-situ (in the same vacuum environment) as the deposition of dielectric layers 46B and 46A. For example, the treatment process may be performed after a delay time, during which the CO₂ and Ar are continuously conducted. In accordance with some embodiments, the flow rate of CO₂ and Ar are kept unchanged. In accordance with alternative embodiments, the flow rate of CO₂ and Ar may be increased or reduced, and then the treatment process 47 is performed.

In accordance with alternative embodiments, the treatment process may be performed ex-situ than the deposition of dielectric layers 46B. The vacuum environment used for the treatment process 47 may be the same as (but in different chambers), or may be different from (with vacuum break in between) the vacuum environment for the deposition of dielectric layer 46B.

In accordance with some embodiments, during the treatment process 47, the wafer temperature of wafer 10 may be in the range between about 75° C. and about 390° C., and may be in the range between about 75° C. and about 100° C. The plasma may be generated using ICP or CCP. The RF-on time (for generating plasma) may be in the range between about 0.2 seconds and about 1.2 seconds, or may be in the range between about 0.4 seconds and about 0.8 seconds. The post-treatment time may also be longer than the RF-on time inside the ALD cycles. The RF power of the post-treatment may be in the range between about 15 watts and about 600 watts. The RF power used in the post-treatment may also be higher than the RF power used during the ALD cycles. For example, the RF power of the post-treatment may be in the range between about 400 watts and about 600 watts.

In accordance with some embodiments, the treatment process 47 is performed an isotropic treatment process, in which no bias power is applied. In accordance with alternative embodiments, the post-treatment is performed through an anisotropic treatment process, in which a bias power is applied. The bias power may be lower than about 15 watts. To ensure the portions of the dielectric layer 46B at the bottom corners of recesses 42 are treated, the post-treatment may also be performed through a tilted treatment, and the tilt angle is adjusted, so that the ions of the treatment gas may reach the bottom corners of recesses 42 directly. For example, FIG. 15 illustrates arrow 43, which represents the direction in which the ions (generated by the treatment processes, including oxygen ions) will reach the bottom corner portions of dielectric layer 46B. The tilt angle α, which is the incident angle of the ions relative to a vertical direction, is selected to ensure that the ions are not blocked by the upper portion of the gate stacks 30. The tilt angle α may be greater than zero degree and smaller than the illustrated tilt angle α, and is related to the aspect ratio of recesses 42.

FIG. 16 illustrates the deposition of dielectric layer 46A. The respective process is illustrated as process 306 in the process flow 300 shown in FIG. 24. Dielectric layer 46A is formed of a material different from the material of dielectric layer 46B. Dielectric layer 46A may comprises a higher nitride atomic percentage than dielectric layer 46B to result in a higher etching selectivity between dielectric layers 46B and 46A in subsequent etching and cleaning processes. For example, dielectric layer 46A may be formed of or comprise silicon nitride (SiN), SiOCN, SiCN, or the like.

In accordance with some embodiments, due to the topology and the property of the deposition process, dielectric layer 46A include sidewall portions 46A-S, bottom portions 46A-B and top portions 46A-T have different properties. For example, in subsequent etching and cleaning processes, the sidewall portions 46A-S of dielectric layer 46A have etching rate ER-S, the top portions 46A-T of dielectric layer 46A have etching rate ER-T, and the bottom portions 46A-B of dielectric layer 46A have etching rate ER-B. The following relationship of etching rates may exist: ER-S>ER-T>ER-B. The sidewall portions 46A-S are thus prone to the damage in subsequent processes.

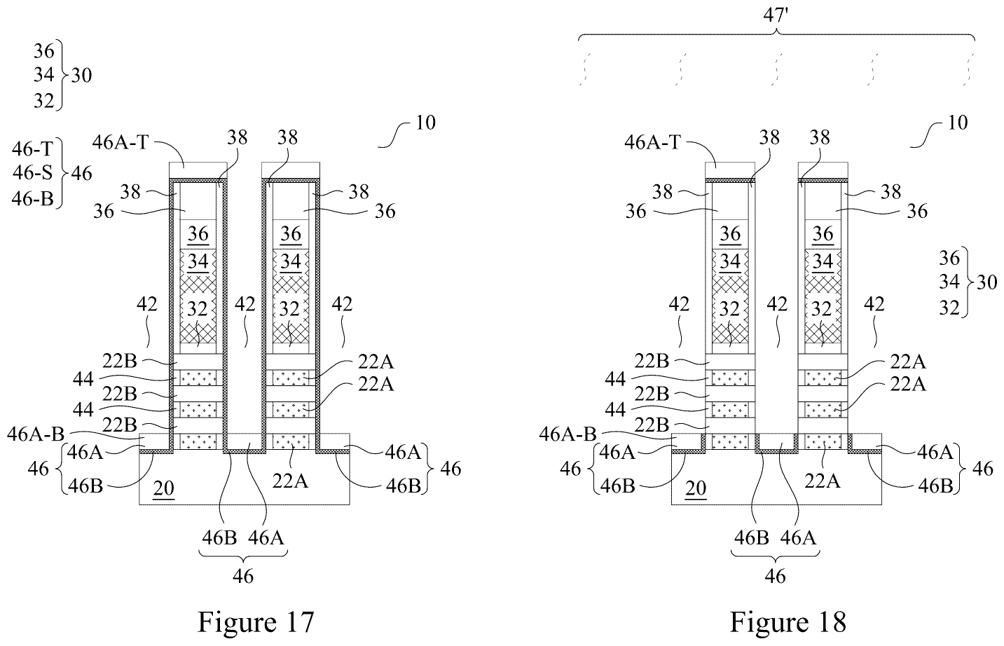

FIG. 17 illustrates the etching of dielectric layer 46A in accordance with some embodiments. The respective process is illustrated as process 308 in the process flow 300 shown in FIG. 24. The etching may be isotropic, and the etching gas or etching solution is selected based on the materials of dielectric layers 46A and 46B. During the etching process, the dielectric layer 46B is unetched (or etched but with a lower etching rate). Since the sidewall portions 46A-S are etched faster than top portions 46A-T, after the etching process, the top portions 46-T may (or may not) have some portions remaining.

The etching may include a dry etching process or a wet etching process. In the dry etching process, a fluorine-containing gas such as CF₄, NF₃, SF₆, CHF₃, ClF₃, or combinations thereof may be used. Other gases such as O₂, N₂, H₂, Ar, NO, and the like, may also be added. In a wet etching process, a chemical solution such as the solution of H₃PO₄ may be used.

At the bottom of recesses 42, there are some bottom portions 46A-B of dielectric layer 46A remaining. This is partially due to that the etching rate ER-B of the bottom portions 46A-B is lower than that of the sidewall portions 46A-S, and partially due to the high-aspect ratio of recesses 42.

FIG. 18 illustrates the etching of dielectric layer 48B, which may be performed using a chemical that etches dielectric layer 48B, but does not etch (or etches but with a lower etching rate) dielectric layer 46A. The respective process is illustrated as process 310 in the process flow 300 shown in FIG. 24. The etching may also include a dry etching process or a wet etching process. For example, when dry etching is performed, the etching gas may include the mixture of NF₂ and NH₃, the mixture of HF and NH₃, or HF. When wet etching is performed, diluted HF solution may be used.

After the etching process, dielectric regions 46, which includes the remaining portions of dielectric layers 46B and 46A, remain at the bottoms of recesses 42. At the top of dummy gate stacks 30, there may be (or may not be) some portions of the dielectric layers 46B and 46A remaining also.

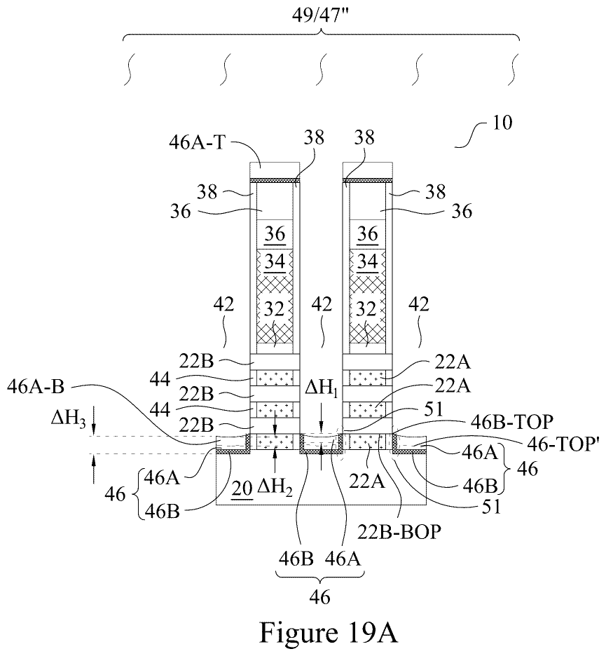

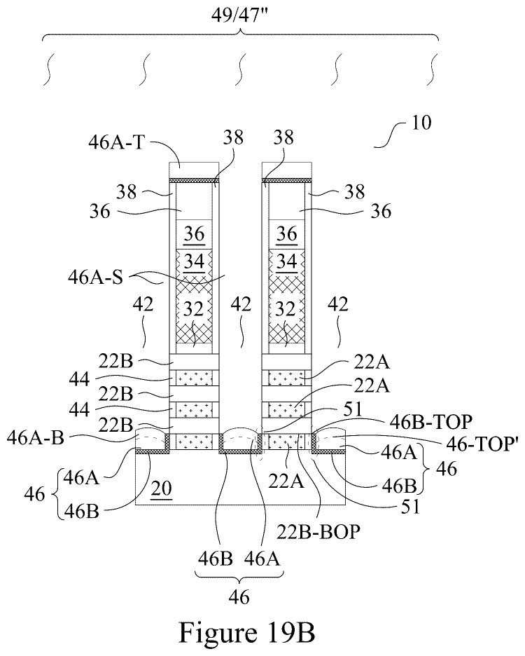

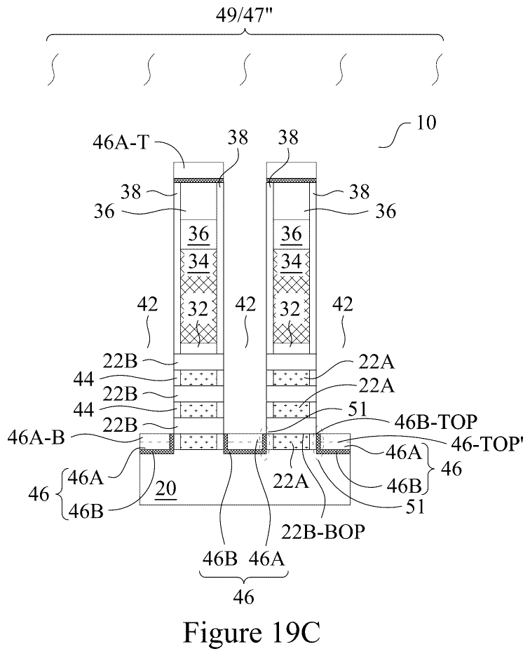

In a subsequent process, as shown in FIGS. 19A, 19B, and 19C, a pre-clean process 49 may be performed to prepare wafer 10 for the subsequent epitaxy process. The respective process is illustrated as process 312 in the process flow 300 shown in FIG. 24. In accordance with some embodiments, the pre-clean process 49 is performed through a dry etching process, which may remove the residues and undesirable chemicals left by the preceding processes. For example, the etching gas may include HF gas in accordance with some embodiments. The etching gas may include the same gas as (or different gas from) the gas for the etching of dielectric layer 46B. For example, HF may be used for both the etching of dielectric layer 46B and the pre-clean process 49.

In accordance with some embodiments, the process gas used for the pre-clean process 49 is capable of etching the material of dielectric layer 46B. Through the treatment process 47 (FIG. 15), the density of dielectric layer 46B is increased, and/or the dangling bonds of dielectric layer 46B are removed. This results in the etching rate of dielectric layer 46B to be reduced in the pre-clean process 49. For example, for some of the pre-clean chemicals such as HF, the etching rate of the dielectric layer 46B before the treatment process 47 would be significantly higher than the etching rate of dielectric layer 46A. This will cause the removal of the sidewall portions of dielectric layer 46B in regions 51 to be undesirably removed if the treatment process 47 is not performed, hence forming voids in regions 51.

The subsequently deposited epitaxy semiconductor regions 48 will fill the voids and may contact substrate 20. This will cause the leakage between source/drain regions 48 (FIG. 19A) and substrate 20 to be increased. Also, the parasitic capacitance between the source/drain regions 48 and the subsequently formed gate electrode will increase.

Through the post-treatment of dielectric layer 46B, the etching rate of dielectric layer 46B during the pre-clean process is reduced. For example, assuming the process gas used for the pre-clean 49 has etching rate ER-46A for etching dielectric layer 46A, etching rate ER-46B1 for etching the dielectric layer 46B that has not been treated by treatment process 47, and etching rate ER-46B2 for etching the dielectric layer 46B that has been treated by treatment process 47, then etching rate ER-46B2 is smaller than etching rate ER-46B1, and ratio ER-46B2/ER-46A is reduced to be smaller than ratio ER-46B1/ER-46A due to the treatment process 47. Etching rate ratio ER-46B2/ER-46B1 may also be smaller than 1, and may be in the range between about 0.6 and about 1.

In accordance with some embodiments, the treatment process 47 causes the etching rate ER-46B2 of the treated dielectric layer 46B to be lower than the etching rate ER-46A of dielectric layer 46A in the pre-clean process 49. In accordance with alternative embodiments, the treatment process 47 causes the etching rate ER-46B2 of the treated dielectric layer 46B to be reduced, but is still equal to or slightly higher than the etching rate ER-46A of dielectric layer 46A during the pre-clean process. Accordingly, in the pre-cleaning process, the sidewall portions of dielectric layer 46B in regions 51 are not etched or etched less, with a significant portion remaining. The adverse increase in the leakage current and the adverse increase of the parasitic capacitance is eliminated.

In accordance with some embodiments, an additional treatment process 47′ (FIG. 18) may be performed at a time after dielectric layer 46A is etched, and before the dielectric layer 46B is etched. In accordance with some embodiments, an additional treatment process 47″ (FIGS. 19A, 19B, and 19C) may be performed after the dielectric layer 46B is etched, and before the pre-cleaning process 49. The details of treatment processes 47′ and 47″ may be essentially the same as that of post-treatment process 47, and are not repeated herein. The treatment processes 47′ and 47″ also have the effect of densifying and removing dangling bonds from dielectric layer 46B, and the effect of reducing the etching rate of dielectric layer 46B in the pre-clean process 49. In accordance some embodiments, at least one or more of the treatment processes 47, 47′, and 47″ may be performed in any combination to achieve the intended effect, while other ones of treatment processes 47, 47′, and 47″ may not be performed

In accordance with some embodiments, as shown in FIG. 19A, after the pre-clean process, the top surface of dielectric regions 46 are concaved. This may be caused by that in the pre-clean process, the etching rate of dielectric layer 46B is lower than that of dielectric layer 46A. The top edges 46B-TOP of the dielectric layer 46B are thus higher than the top surfaces of dielectric layer 46A. The top edges 46B-TOP of dielectric layer 46B may be level with or lower than the bottom surface 22B-BOT of the bottommost semiconductor nanosheet 22B. In accordance with some embodiments, the top surfaces of dielectric regions 46 are lower than the bottom surface 22B-BOT, and are represented by dashed lines 46-TOP′.

In accordance with alternative embodiments, as shown in FIG. 19B, after the pre-clean process, dielectric regions 46 have convex top surfaces. This may be caused by that in the pre-clean process, the etching rate of dielectric layer 46B is higher than that of dielectric layer 46A. The top edges 46B-TOP of the dielectric layer 46B are thus lower than the top surfaces of dielectric layer 46A. The top edges 46B-TOP of dielectric layer 46B may also be level with or lower than the bottom surface 22B-BOT. In accordance with some embodiments, the top surfaces of dielectric regions 46 are lower than the bottom surface 22B-BOT, and are represented by dashed lines 46-TOP′.

In accordance with yet alternative embodiments, as shown in FIG. 19C, after the pre-clean process, dielectric regions 46 have planar top surfaces. This may be caused by that in the pre-clean process, the etching rate of dielectric layer 46B is equal to that of dielectric layer 46A. The top edges 46B-TOP of the dielectric layer 46B are thus level with the top surfaces of dielectric layer 46A. The top edges 46B-TOP of dielectric layer 46B may also be level with or lower than the bottom surface 22B-BOT. In accordance with some embodiments, the top surfaces of dielectric regions 46 are lower than the bottom surface 22B-BOT, and are represented by dashed lines 46-TOP′.

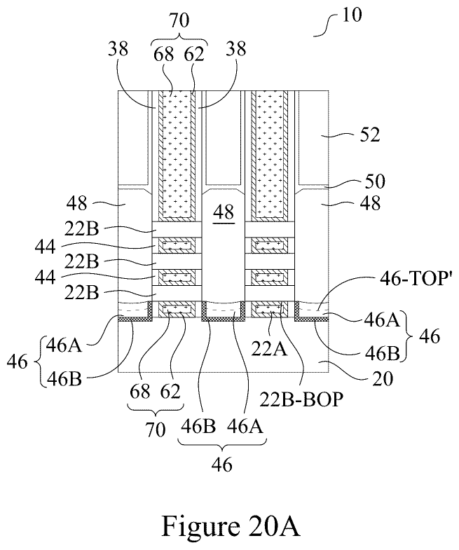

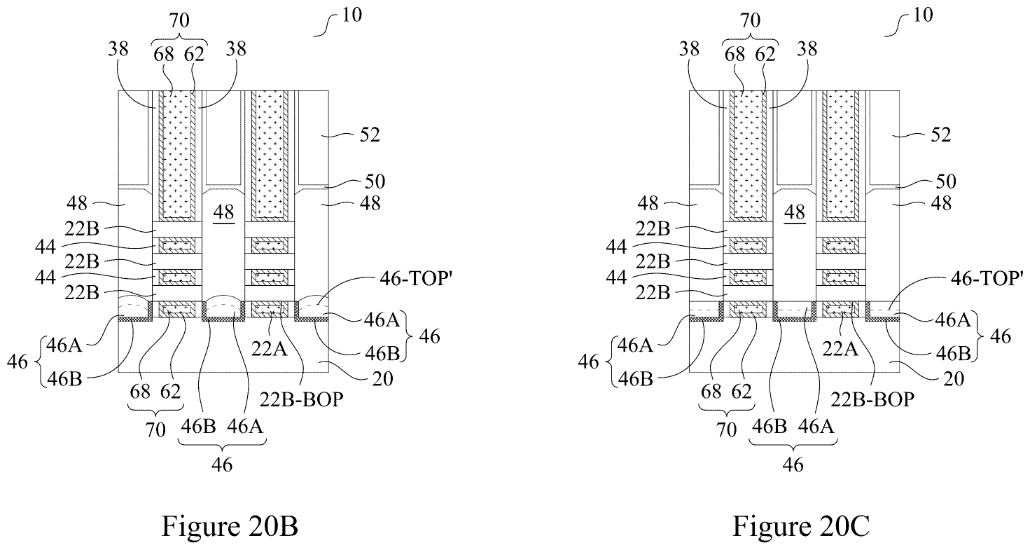

In the embodiments shown FIGS. 19A and 19B, when dielectric regions 46 have top surfaces 46-TOP′, which is shown as being dashed, the height difference ΔH1 (FIG. 19A) between bottom surface 22B-BOT and the topmost edges of dielectric layer 46B (which are part of 46-TOP′) may be equal to or less than about 0.6 nanometers, or equal to or less than (ΔH₃)/2, wherein ΔH₃ (FIG. 19A) is the height difference between the bottom surface 22B-BOT and the top surfaces (which are also the bottom of dielectric regions 46) of the bulk portion of substrate 20. Otherwise, the parasitic capacitance between the subsequently formed source/drain regions 48 (FIGS. 20A, 20B, and 20C) and gate electrodes 68 will increase undesirably.

The recessing depth ΔH2 of the top surface of dielectric regions 46 may be equal to or smaller than (ΔH₃)/2 also. Otherwise, dielectric regions 46 may have breaks, and the leakage current between the subsequently formed source/drain regions 48 (FIG. 20A) and substrate 20 will occur.

FIGS. 20A, 20B, and 20C illustrate the formation of epitaxy source/drain regions 48. The respective process is illustrated as process 314 in the process flow 300 shown in FIG. 24, and shown as process 216 in the process flow 200 shown in FIG. 23. FIGS. 20A, 20B, and 20C correspond to FIGS. 19A, 19B, and 19C, respectively, and also show the source/drain regions 48 also. The formation of source/drain regions 48 have been discussed referring to FIGS. 9A and 9B.

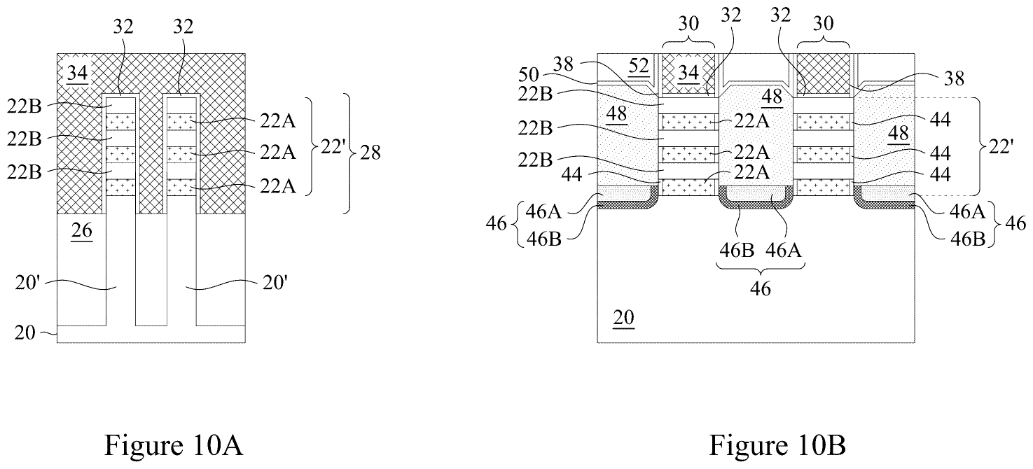

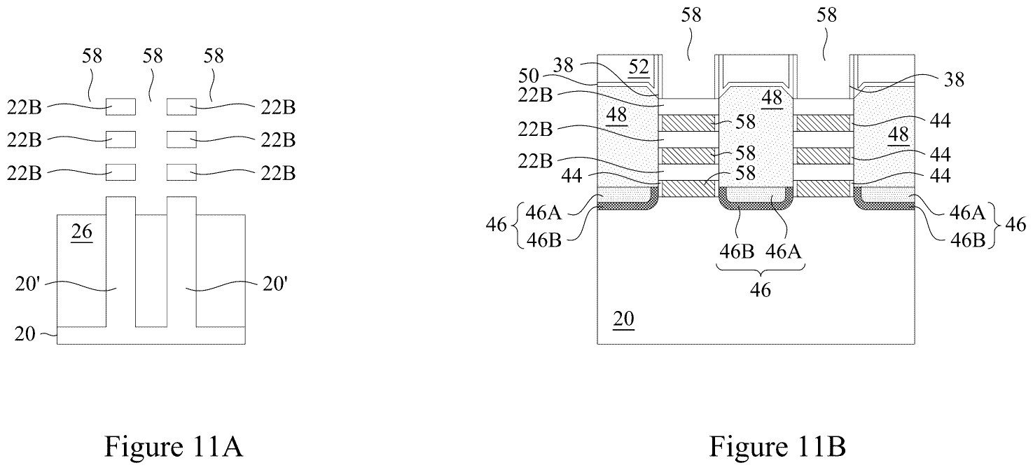

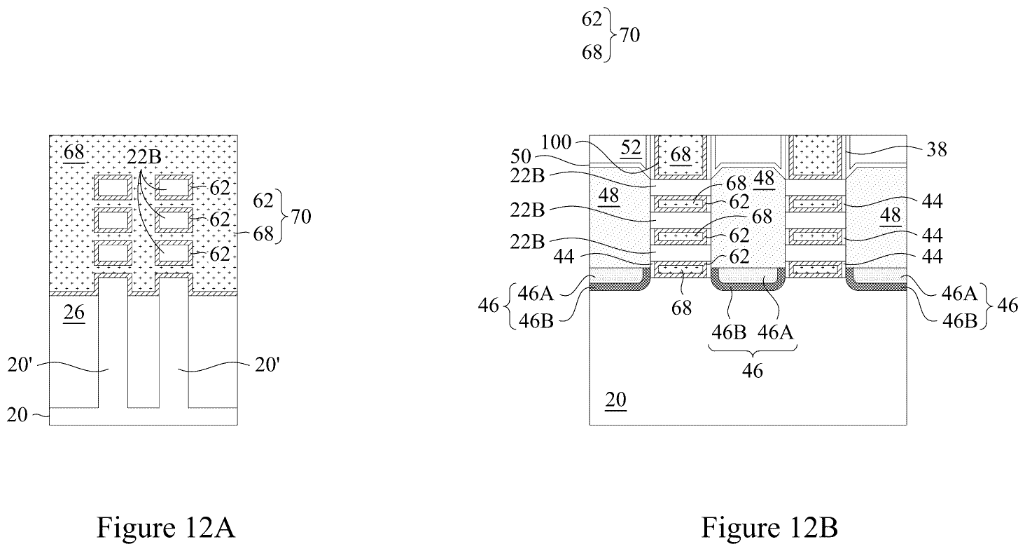

Next, Contact Etch Stop Layer (CESL) 50 and Inter-Layer Dielectric (ILD) 52 are formed as shown in FIGS. 20A, 20B, and 20C. These features are also shown in FIGS. 10A and 10B, as will be discussed subsequently. Replacement gate stacks 70 are also formed, and the forming processes are shown in FIGS. 11A, 11B, 12A, and 12B. The formation details of these features are discussed referring to the subsequently discussed FIGS. 10A and 10B through FIGS. 14A and 14B.

FIGS. 10A and 10B through FIGS. 14A and 14B illustrate the details of some of the features as discussed referring to FIGS. 20A, 20B, and 20C. These figures may have the corresponding numbers followed by letter A or B. The figure with the figure number having the letter A indicates that the corresponding figure shows a reference cross-section same as the reference cross-section A2-A2 in FIG. 4. The figures with the figure numbers having the letter B indicate that the corresponding figures show a reference cross-section same as the reference cross-section B-B in FIG. 4.

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown in FIG. 23. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 220 in the process flow 200 shown in FIG. 23. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

Next, dummy gate electrodes 34 and dummy gate dielectrics 32 (and hard masks 36, if remaining) are removed in one or more etching processes, so that recesses 58 are formed, as shown in FIGS. 11A and 11B. The respective process is illustrated as process 222 in the process flow 200 shown in FIG. 23. In accordance with some embodiments, dummy gate electrodes 34 and dummy gate dielectrics 32 are removed through an anisotropic dry etch process(es). For example, the etching process may be performed using reaction gas(es) that selectively etch dummy gate electrodes 34 and dummy gate dielectrics 32 at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown in FIG. 23. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH₄OH), or the like may be used to remove sacrificial layers 22A.

Referring to FIGS. 12A and 12B, gate dielectrics 62 and gate electrodes 68 are formed, hence forming replacement gate stacks 70. The respective process is illustrated as process 226 in the process flow 200 shown in FIG. 23. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

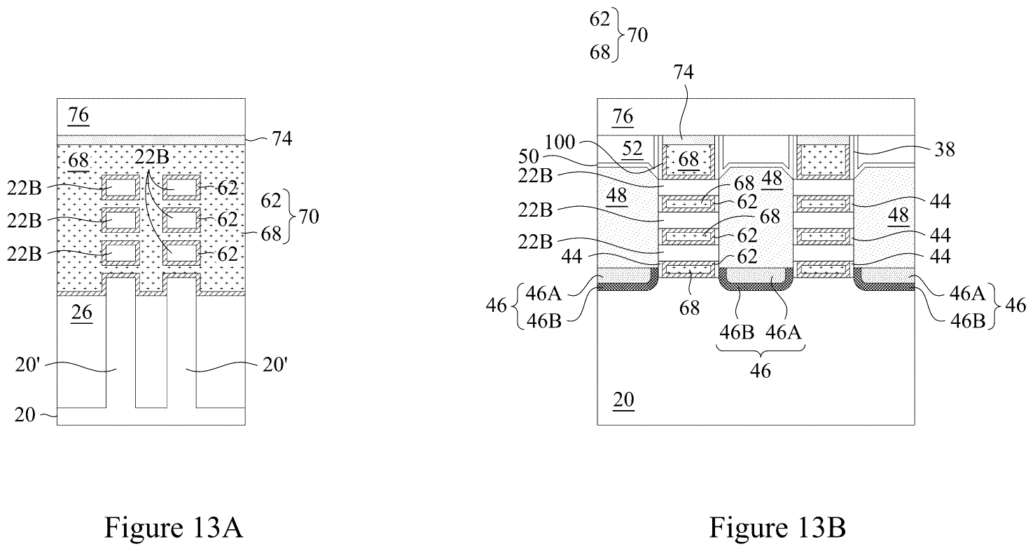

In the processes shown in FIGS. 13A and 13B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 228 in the process flow 200 shown in FIG. 23.

As further illustrated by FIGS. 13A and 13B, ILD 76 is deposited over ILD 52 and over gate masks 74. The respective process is illustrated as process 230 in the process flow 200 shown in FIG. 23. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

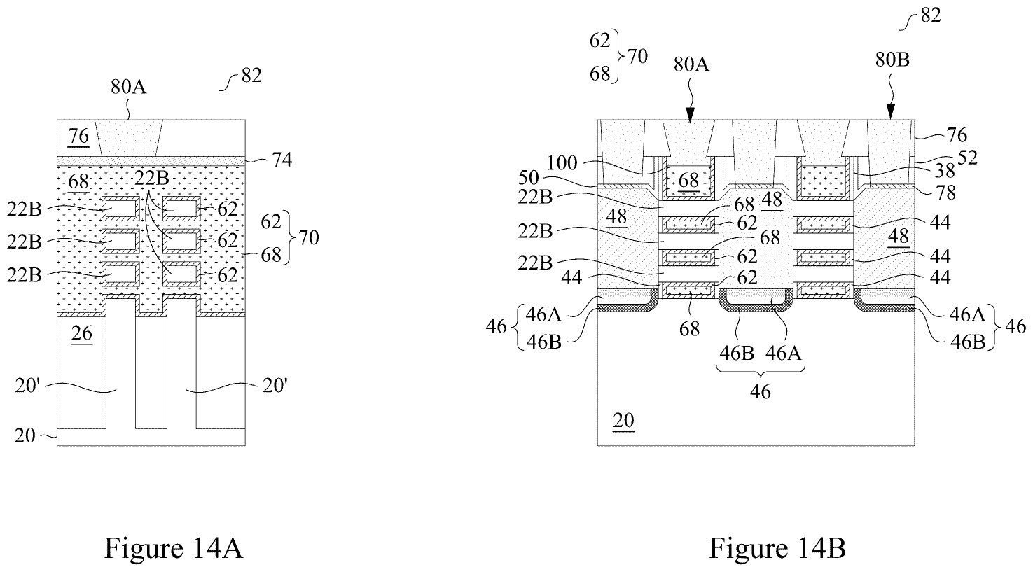

In FIGS. 14A and 14B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process, such as RIE, NBE, or the like. Although FIG. 14B illustrates that contact plugs 80A and 80B are in a same cross-section, in various embodiments, contact plugs 80A and 80B may be formed in different cross-sections, thereby reducing the risk of shorting with each other.

After the recesses are formed, silicide regions 78 are formed over source/drain regions 48. The respective process is illustrated as process 232 in the process flow 200 shown in FIG. 23. Contact plugs 80B are then formed over silicide regions 78. Also, contacts 80A (may also be referred to as gate contact plugs) are also formed in the recesses, and are over and contacting gate electrodes 68. The respective process is illustrated as process 234 in the process flow 200 shown in FIG. 23. Transistor 82 is thus formed.

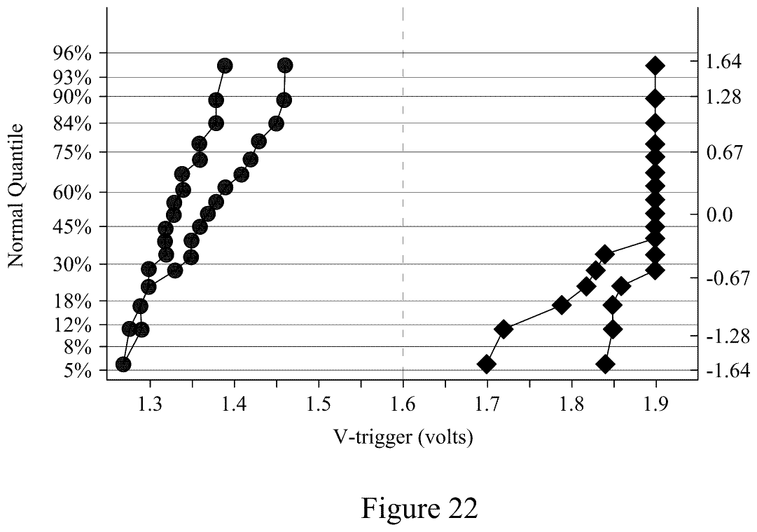

FIG. 22 illustrate some experiment results obtained from some samples. The X-represents the V-trigger voltages, which are the voltages needed to turn on parasitic transistors in the structure of the embodiments, so that current is conducted to substrate 20 as leakage. An example specification is that the V-trigger voltage needs to be greater than 1.6 volts. The Y-axis represents the normal quantile of multiple samples. The samples shown in left half of the figure are obtained from the samples in which the formation of dielectric regions does not include treatment 47. It is observed that some samples have V-trigger voltages smaller than about 1.3 volts, and all of the samples have V-trigger voltages smaller than about 1.45 volt, so that these samples do not meet specification.

The samples shown on the right half of the figure are obtained from the samples in which the formation of dielectric regions include treatment process 47. It is observed that all of the samples have V-trigger voltages greater than 1.6 volt, so that these samples meet specification.

The embodiments of the present disclosure have some advantageous features. Through post-treatment processes during the formation of the bottom dielectric layer, the undesirable etching of the corner portions of the bottom dielectric layer is eliminated. The leakage currents between source/drain regions and the underlying substrate are reduced or eliminated. The parasitic capacitance between source/drain regions and gate electrodes is also reduced.

In accordance with some embodiments of the present disclosure, a method comprises forming a gate stack over a semiconductor region; etching the semiconductor region to form a source/drain recess aside of the gate stack; depositing a first dielectric layer, wherein a portion of the first dielectric layer is in the source/drain recess; performing a treatment process on the first dielectric layer; depositing a second dielectric layer on the first dielectric layer; etching the second dielectric layer and the first dielectric layer, wherein a first portion of the first dielectric layer and a second portion of the second dielectric layer remain at a bottom of the source/drain recess to form a dielectric region; and depositing a source/drain region in the source/drain recess and over the dielectric region.

In an embodiment, the depositing the first dielectric layer comprises depositing an oxygen-containing dielectric layer, and the depositing the second dielectric layer comprises depositing a nitrogen-containing dielectric layer. In an embodiment, the treatment process is performed using an oxygen-containing process. In an embodiment, the treatment process comprises a plasma treatment process. In an embodiment, the method further comprises, after the dielectric region is formed and before the source/drain region is deposited, performing a pre-clean process. In an embodiment, the pre-clean process is performed using an HF gas.

In an embodiment, the first dielectric layer is deposited using plasma enhanced atomic layer deposition comprising a plurality of cycles, and wherein the treatment process comprises turning on a radio-frequency power to generate a plasma. In an embodiment, the depositing the first dielectric layer comprises conducting a process gas as a precursor, and wherein the treatment process is also performed using the process gas to generate the plasma.

In an embodiment, the depositing the first dielectric layer comprises conducting a first process gas as a precursor, and wherein the treatment process is performed using a second process gas different from the first process gas to generate the plasma. In an embodiment, the treatment process is performed using carbon dioxide (CO₂) as a process gas. In an embodiment, the semiconductor region comprises a semiconductor nanosheet, wherein the semiconductor nanosheet is comprised in a protruding feature comprising additional semiconductor nanosheets stacked on the semiconductor nanosheet.

In accordance with some embodiments of the present disclosure, a method comprises forming a protruding feature comprising a first sacrificial nanosheet over a bulk semiconductor substrate; a first semiconductor nanosheet over the first sacrificial nanosheet; a second sacrificial nanosheet over the first semiconductor nanosheet; and a second semiconductor nanosheet over the second sacrificial nanosheet; forming a gate stack on a sidewall and a top surface of the protruding feature; etching the protruding feature to form a recess, with a first bottom of the recess is lower than a second bottom of the first semiconductor nanosheet; depositing a first dielectric layer into the recess; performing a treatment process on the first dielectric layer; depositing a second dielectric layer on the first dielectric layer; etching sidewall portions of the first dielectric layer and the second dielectric layer, with a dielectric region being left at the first bottom of the recess, wherein the dielectric region comprises a first bottom portion of the first dielectric layer and a second bottom portion of the second dielectric layer; and forming a source/drain region on the dielectric region.

In an embodiment, a top surface of the dielectric region is lower than the second bottom of the first semiconductor nanosheet. In an embodiment, a top surface of the dielectric region is level with the second bottom of the first semiconductor nanosheet. In an embodiment, the method further comprises, after the dielectric region is formed, performing a pre-clean process, wherein the treatment process results in the first bottom portion of the first dielectric layer to have a lower etching rate during the pre-clean process than the first dielectric layer at a time before the treatment process.

In an embodiment, the treatment process is performed using an oxygen-containing process gas. In an embodiment, the method further comprises removing the first sacrificial nanosheet and the second sacrificial nanosheet; and forming a replacement gate stack, wherein the replacement gate stack comprise portions in spaces left by the first sacrificial nanosheet and the second sacrificial nanosheet to be removed.

In accordance with some embodiments of the present disclosure, a method comprises etching a semiconductor nanosheet to form a source/drain recess, wherein the source/drain recess comprises a first bottom lower than a second bottom of the semiconductor nanosheet; depositing a first dielectric layer, wherein a portion of the first dielectric layer is in the source/drain recess, and the first dielectric layer comprises a first dielectric material; performing a treatment process on the first dielectric layer to convert the first dielectric material to a second dielectric material; depositing a second dielectric layer on the first dielectric layer; etching the second dielectric layer and the first dielectric layer, wherein a first portion of the first dielectric layer and a second portion of the second dielectric layer remain at a bottom of the source/drain recess to form a dielectric region; performing a pre-clean process using an etching gas, wherein the etching gas is capable of etching the first dielectric material with a first etching rate, and is capable of etching the second dielectric material with a second etching rate, and wherein the second etching rate is lower than the first etching rate; and growing a semiconductor region in the source/drain recess through an epitaxy process.

In an embodiment, the pre-clean process results in the dielectric region to have a concave top surface. In an embodiment, the pre-clean process results in the dielectric region to have a convex top surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack over a semiconductor region;
etching the semiconductor region to form a source/drain recess aside of the gate stack;
depositing a first dielectric layer, wherein a portion of the first dielectric layer is in the source/drain recess;
performing a treatment process on the first dielectric layer;
depositing a second dielectric layer on the first dielectric layer;
etching the second dielectric layer and the first dielectric layer, wherein a first portion of the first dielectric layer and a second portion of the second dielectric layer remain at a bottom of the source/drain recess to form a dielectric region; and
depositing a source/drain region in the source/drain recess and over the dielectric region wherein the depositing the first dielectric layer comprises depositing an oxygen-containing dielectric layer, and the depositing the second dielectric layer comprises depositing a nitrogen-containing dielectric layer, and wherein the treatment process is performed using an oxygen-containing process.
